(19) United States
(12) Patent Application Publication
(10) Pub. No.: US 2003/0150645 A1
(43) Pub. Date: Aug. 14, 2003

(54) Method and apparatus for coupling a microelectronic device package to a circuit board

(76) Inventor: Chia-Pin Chiu, Tempe, AZ (US)

Correspondence Address: Blakely, Sokoloff, Taylor & Zafman LLP, Seventh Floor, 12400 Wilshire Boulevard, Los Angeles, CA, 90025-1030, US

(21) Appl. No.: 10/075,513

(22) Filed: Feb. 12, 2002

(51) Int. Cl. H05K 1/11; H05K 3/32

(52) U.S. Cl. 174/264; 174/260; 174/262; 29/832; 29/840; 29/852

(57) ABSTRACT

Multiple through holes in a printed circuit board (PCB) are filled with a malleable, electrically conductive material, such as an elastomer containing a concentration of conductive particles. The material in each through hole forms an electrical contact at which a solder ball or pin of a ball grid array (BGA) or pin grid array (PGA) of a microelectronic package, respectively, will be coupled to the PCB.

### FIELD OF THE INVENTION

The present invention pertains to techniques for coupling microelectronic device packages to printed circuit boards. More particularly, the present invention relates to a technique for coupling a microelectronic device package to a printed circuit board without using a reflow or wave-solder process.

### BACKGROUND OF THE INVENTION

In microelectronic device manufacturing, a microelectronic circuit chip, or “die”, is commonly mounted to a “package” before it is integrated into a larger system. The package serves to protect the die and may provide a standardized interface between the die and the system in it will be used. The package with the integrated die is subsequently mounted to a printed circuit board (PCB), such as a motherboard in a computer system.

Two common types of interface for connecting these components together are the ball grid array (BGA) and the pin grid array (PGA). In the case of a BGA, the input/output (I/O) terminals of a device are formed by an array of round solder balls, while in the case of a PGA they are formed by an array of metal pins in the case of a PGA. FIGS. 1 and 2 show examples (in side cross-section) of how BGA components and PGA components, respectively, can be mounted directly to a PCB according to the current state of the art. In FIG. 1, a semiconductor die 1 is mounted to a device package 2, which is coupled directly to a PCB 3 (e.g., a motherboard) by solder balls 4 of a BGA. The package 2 can be mounted directly to the PCB 3 using a solder reflow process. In FIG. 2, the die 1 is mounted to a package 6, which is coupled directly to a PCB 7 (e.g., a motherboard) by pins 8 of a PGA. The package 6 can be mounted directly to the PCB 7 by inserting the pins 8 into through holes 9 on the PCB 7 and then using a wave-solder process.

One problem with directly mounting a BGA or PGA directly to a PCB is that it is difficult if not impossible to interchange or rework components once they are mounted to the PCB. Consequently, sockets are often used to mount a BGA or PGA to a PCB, to provide greater parts interchangeability and reworkability.

With each device generation, particularly for microprocessors, the number of inputs and outputs required in the device tends to increase. As the pin/ball count increases, the cost of a traditional PGA/BGA socket tends to increase. In addition, the traditional socket requires a surface mount or wave-soldering process to mount it on the motherboard, which are expensive and complicated processes.

Moreover, in view of the steadily increasing demand for smaller, more mobile computing and communication devices, there is an increasing emphasis on conserving the amount of space consumed by electronic components within a system. Although BGA/PGA sockets provide interchangeability and reworkability, they also add to the total height of electronic components on a PCB, thereby working against space conservation efforts.

Consequently, it is desirable to have an alternative technique for mounting microelectronic components to a PCB, which overcomes these disadvantages.

### BRIEF DESCRIPTION OF THE DRAWINGS

The present invention is illustrated by way of example and not limitation in the figures of the accompanying drawings, in which like references indicate similar elements and in which:

FIG. 1 illustrates how a BGA can be mounted to a PCB;

FIG. 2 illustrates how a PGA can be mounted to a PCB;

FIG. 3 illustrates two orthogonal views of the PCB with multiple through holes, each filled with a conductive elastomer;

FIG. 4A shows how a BGA can be mounted to the PCB of FIG. 3;

FIG. 4B shows how a PGA can be mounted to the PCB of FIG. 3;

FIGS. 5A through 5D show various techniques for fastening a BGA-based microelectronic component to a PCB; and

FIGS. 6A through 6D are cross-sectional side views of the PCB showing how the elastomer can be electrically coupled to the electrical traces of the PCB.

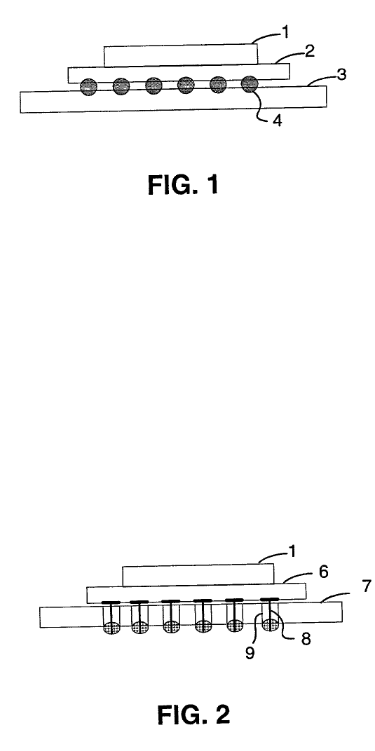

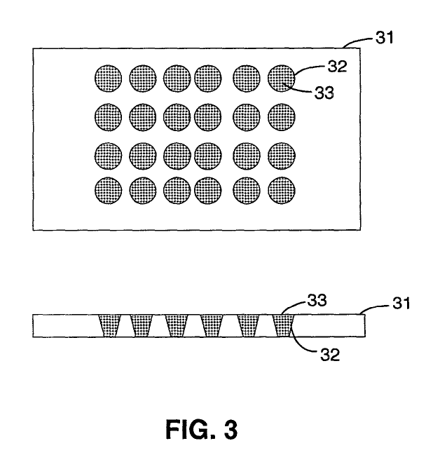

### DETAILED DESCRIPTION

A method and apparatus for coupling a microelectronic device package to a printed circuit board without using a reflow or wave-solder process are described. Note that in this description, references to “one embodiment” or “an embodiment” mean that the feature being referred to is included in at least one embodiment of the present invention. Further, separate references to “one embodiment” in this description do not necessarily refer to the same embodiment; however, neither are such embodiments mutually exclusive, unless so stated and except as will be readily apparent to those skilled in the art. For example, a feature, structure, act, etc. described in one embodiment may also be included in other embodiments. Thus, the present invention can include a variety of combinations and/or integrations of the embodiments described herein.

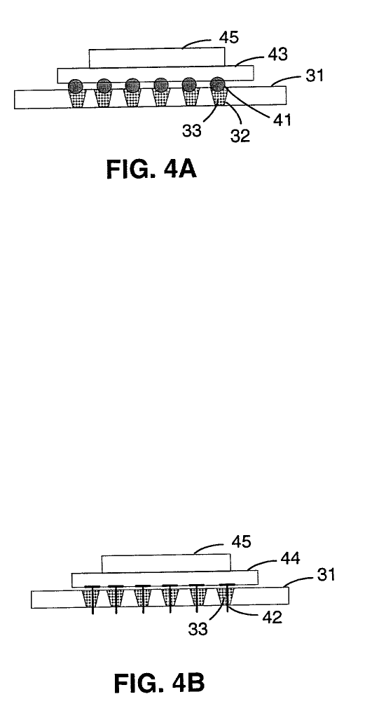

Refer now to FIG. 3, which illustrates a top view and an orthogonal side cross-section view of a PCB 31 in accordance with the present invention. Multiple through holes 32 are drilled through the PCB (e.g., motherboard) 31 substrate, and each through hole 32 is then filled with a malleable, electrically conductive material 33. In one embodiment the material 33 is a conductive elastomer (as henceforth assumed herein to facilitate description), e.g., an elastomer containing a certain concentration of conductive particles. The elastomer 33 is made to be flush with the top surface and bottom surface of the PCB 31.

The elastomer 33 in each through hole 32 forms an electrical contact at which a solder ball or pin of a BGA or PGA of a microelectronic package, respectively, will be coupled to the PCB 31. As shown in the side cross-section view, the through holes 32 are tapered toward the bottom side of the PCB 31 to prevent the elastomer 33 from being pushed out the bottom side of the PCB 31 when the package is attached to the PCB 31.

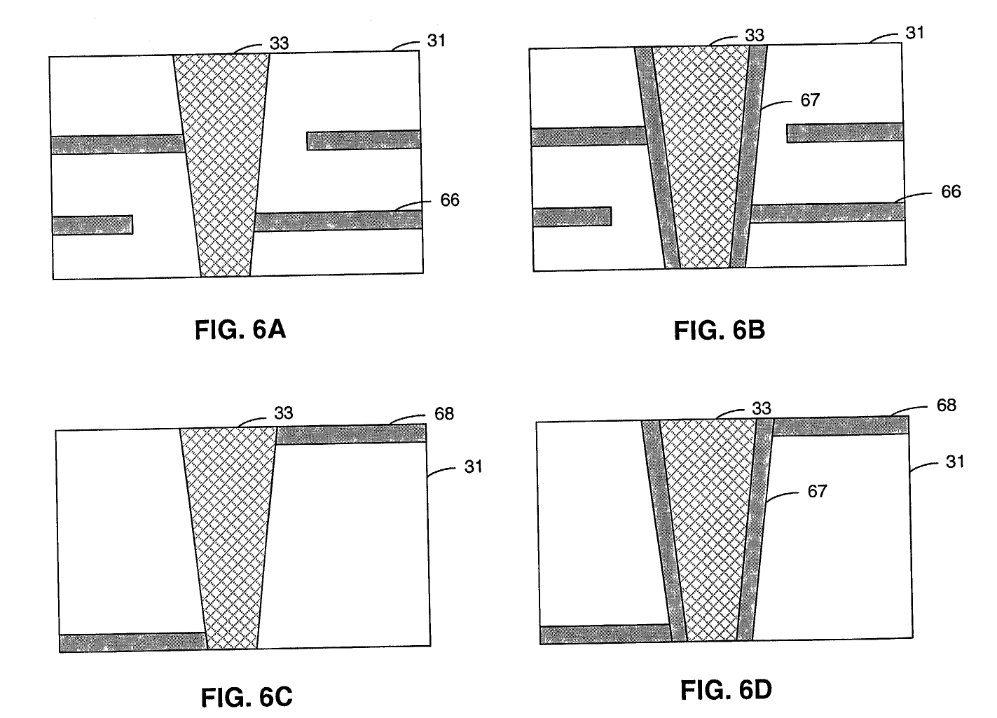

The elastomer 33 can be connected directly, or through conductive plating on the wall of the through holes, to surface traces or internal conductive planes inside the motherboard, as shown in FIGS. 6A through 6D. FIG. 6A shows the elastomer 33 directly in contact with the internal planes 66 of the PCB 31. FIG. 6B shows the elastomer 33 in contact with the internal planes 66 of the PCB 31 through the conductive (e.g., copper) plating 67 on the wall of the through hole. FIG. 6C shows the elastomer 33 directly in contact with the surface planes 68 of the PCB 31. FIG. 6D shows the elastomer 33 in contact with the surface planes 68 of the PCB 31 through the conductive (e.g., copper) plating 67 on the wall of the through hole. Note that these embodiments can be combined in a given PCB.

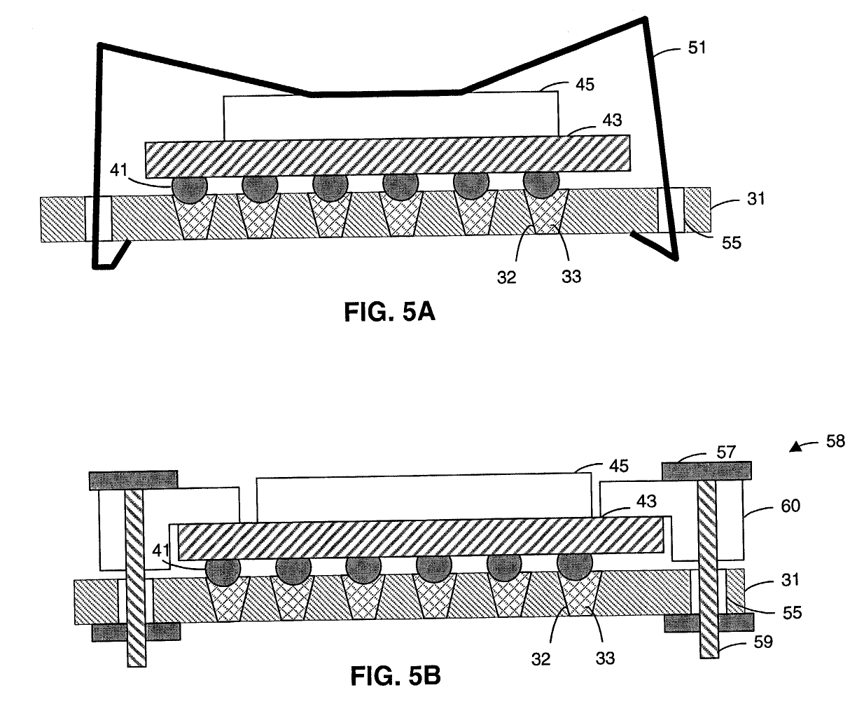

FIGS. 4A and 4B show examples of the application of the above described technique. Specifically, FIG. 4A shows how a BGA-based package 43 can be mounted to the PCB 31, while FIG. 4B shows how a PGA-based package 44 can be mounted to the PCB 31. In FIG. 4A, the BGA is directly mounted on the PCB 31 by applying clamping force between the solder balls 41 and the elastomer 33, causing a slight compression of the elastomer 33. As described further below, the clamping force could come from the thermal enabling solution such as heat sink clip, heat sink joint bolt, or heat sink spring. The clamping force can also come from an independent clamping mechanism regardless of the thermal solutions.

In FIG. 4B, the PGA is directly mounted on the PCB 31 by inserting the package pins 42 through the elastomer 33. The package 43 can then be held on the motherboard by either a heat sink clamping mechanism or an independent clamping mechanism.

The elastomer 33 generally may be of the type commonly used in electronics applications, such as used to make gaskets in electromagnetic interference (EMI) applications. A typical elastomer used in such an application is soft enough for a package pin to penetrate through it. A typical elastomer thickness can be compressed approximately 15 percent under certain pressure so that the elastomer can conform to an irregular surface shape, such as a solder ball. However, most such elastomers do not have good electrical conductivity. To make the elastomer electrically conductive, therefore, particles of silver (Ag), copper (Cu), nickel (Ni), or gold (Au), or other suitable conductive element(s), can be added into the elastomer while it is in liquid form, prior to filling it in the through holes 32 of the PCB 31. A concentration of conductive particles of at least approximately 50 percent is believed to be sufficient to provide adequate conductivity.

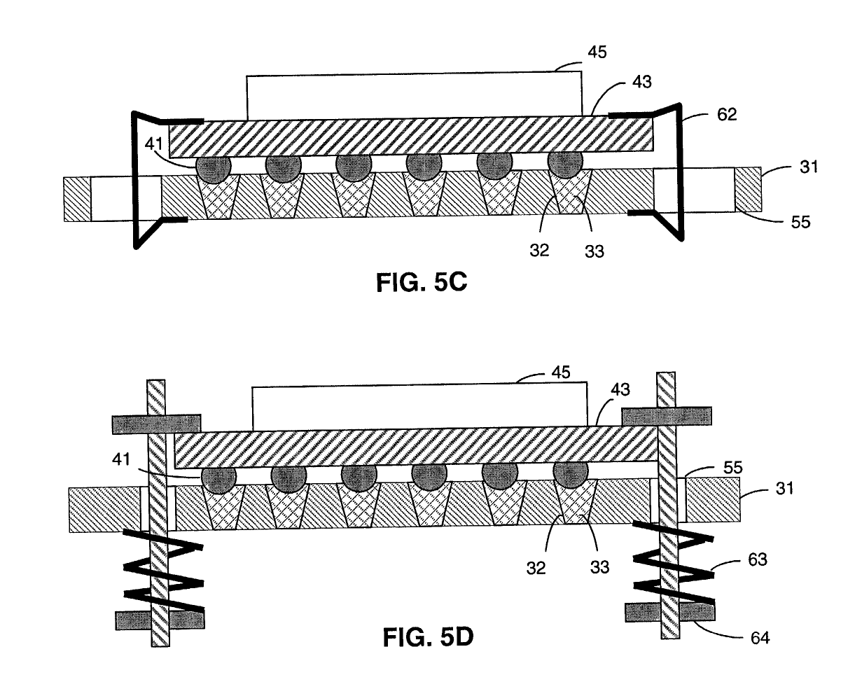

FIGS. 5A through 5D show various techniques for fastening a BGA- or PGA-based microelectronic component to the PCB 31 (only BGA-based embodiments are shown, to simplify the description). FIG. 5A shows an embodiment in which a single clip 51 is used to provide the clamping force. The clip 51 applies pressure against the top surface of the die 45 and the bottom surface of the PCB 31. The clip 51 passes through two additional through holes 55 in the PCB 31.

FIG. 5B shows an embodiment in which a clamp-and-bolt assembly 58 is used to provide the clamping force between the package 43 and the PCB 31. In multiple locations, the combination of a bolt 59 and nut 57 apply a force against a clamp 60 to compress the package 43 against the PCB 31.

FIG. 5C shows an embodiment to similar to FIG. 5A, except that multiple clips 62 are used to provide the clamping force, which apply pressure directly against the package 43 rather than against the die 45.

FIG. 5D shows a spring-based embodiment. In multiple locations, a compressed spring 63 applies a force against the bottom of the PCB 31 and against a nut 64 to provide the clamping force.

From the foregoing description, the following advantages of this technique will be apparent. The contacts for coupling the pins or solder balls to the PCB are built into the PCB; no separate socket is required. Furthermore, the malleable, compressible nature of the elastomer allows a device package to be removed from the PCB and a new package to be mounted without damage, thereby providing part interchangeability and reworkability. The technique can be used for both PGA and BGA types of packages and can be extended for higher pin/ball count and smaller pin/ball pitch. In addition, the compressibility of the elastomer can compensate for different ball height (e.g., due to design or assembly variation) or warping of the PCB substrate. The technique can also compensate for the problem of pins' actual locations varying from their ideal (design) locations. The technique may also avoid current (Imax) constraints caused by the long electrical connection paths from the PCB to the package when sockets are used.

Thus, a method and apparatus for coupling a microelectronic device package to a printed circuit board without using a reflow or wave-solder process have been described. Although the present invention has been described with reference to specific exemplary embodiments, it will be evident that various modifications and changes may be made to these embodiments without departing from the broader spirit and scope of the invention as set forth in the claims. Accordingly, the specification and drawings are to be regarded in an illustrative sense rather than a restrictive sense.

What is claimed is:

1. A circuit board comprising:
a substrate;
a plurality of through holes in the substrate; and
a malleable, electrically conductive material filled within each of the through holes.

2. A circuit board as recited in claim 1, wherein the material is to receive an electrical contact of an electronic component when the electronic component is coupled to the circuit board.

3. A circuit board as recited in claim 2, wherein each said electrical contact is a pin.

4. A circuit board as recited in claim 2, wherein each said electrical contact is a solder ball.

5. A circuit board as recited in claim 1, wherein the material is an elastomer.

6. A circuit board as recited in claim 1, wherein the through holes are tapered.

7. A circuit board comprising:
a substrate having a first surface and a second surface parallel to the first surface; and
a plurality of tapered through holes in the substrate from the first surface to the second surface;
each of the through holes filled with an electrically conductive elastomer to receive a separate one of a plurality of electrical contacts of an electronic component, to couple the electronic component to the circuit board.

8. A circuit board as recited in claim 7, wherein the electrical contacts are pins that are inserted into the elastomer when the electronic component is coupled to the circuit board.

9. A circuit board as recited in claim 7, wherein the electrical contacts are solder balls that compress the elastomer when the electronic component is coupled to the circuit board.

10. A circuit board as recited in claim 7, wherein the elastomer includes conductive particles interspersed therein.

11. An apparatus comprising:
a circuit board including
a substrate having a first surface and a second surface parallel to the first surface,
a plurality of tapered through holes in the substrate from the first surface to the second surface, and
an electrically conductive elastomer filling each of the through holes; and
an electronic component coupled to the circuit board, the electronic component having a plurality of electrical contacts, each in physical and electrical contact with the elastomer in a separate one of the through holes.

12. An apparatus as recited in claim 11, wherein the electrical contacts are pins, each inserted into the elastomer in a separate one of the through holes.

13. An apparatus as recited in claim 11, wherein the electrical contacts are solder balls, each of the solder balls compressing the elastomer in a separate on of the through holes.

14. An apparatus as recited in claim 13, further comprising a fastener to secure the electronic component to the circuit board.

15. An apparatus as recited in claim 11, wherein the elastomer includes conductive particles interspersed therein.

16. A method of manufacturing a circuit board, the method comprising:
creating a plurality of through holes in a circuit board substrate; and
causing each of the through holes to be filled with a malleable, electrically conductive material.

17. A method as recited in claim 16, wherein the material is an elastomer.

18. A method as recited in claim 16, wherein the through holes are tapered.

19. A method of mounting an electronic component to a circuit board, the method comprising:
aligning a plurality of electrical contacts of the electronic component with a corresponding plurality of electrical contacts of the circuit board, wherein each of the electrical contacts of the circuit board comprises a through hole in the circuit board filled with an electrically conductive elastomer; and
placing the electrical contacts of the electronic component in contact with the electrical contacts of the circuit board.

20. A method as recited in claim 19, wherein the electrical contacts of the electronic component are pins of a pin grid array, and wherein said placing the electrical contacts of the electronic component in contact with the electrical contacts of the circuit board comprises inserting each of the pins into the conductive elastomer in a separate one of the through holes.

21. A method as recited in claim 19, wherein the electrical contacts of the electronic component are solder balls of a ball grid array, and wherein said placing the electrical contacts of the electronic component in contact with the electrical contacts of the circuit board comprises compressing each of the solder balls against the conductive elastomer in a separate one of the through holes.

22. A method as recited in claim 21, further comprising securing the electrical component to the circuit board.

23. A circuit board comprising:
a substrate; and
coupling means for removably coupling an electronic component to the substrate physically and electrically, without using a socket.

24. A circuit board as recited in claim 23, wherein said coupling means comprises a plurality of through holes.

25. A circuit board as recited in claim 24, wherein said coupling means further comprises an elastomer filled in each of the plurality of through holes.
